(19) United States
(12) Patent Application Publication
(10) Pub. No.: US 2024/0271655 A1
(43) Pub. Date: Aug. 15, 2024

(54) ROTATION TRANSMISSION SHAFT UNIT, AND MOTOR, INVERTER TEST BENCH, AND EMC TEST EQUIPMENT DEVICE USING SAID SHAFT UNIT

(71) Applicants: Ohtama Co., Ltd., Inagi-shi, Tokyo (JP); TODA RACING Co., Ltd., Kurashiki-shi, Okayama (JP)

(72) Inventors: Masaru Nakayama, Kashima-shi, Ibaraki (JP); Koji Kajitani, Soja-shi, Okayama (JP)

(73) Assignees: Ohtama Co., Ltd., Inagi-shi, Tokyo (JP); TODA RACING Co., Ltd., Kurashiki-shi, Okayama (JP)

(21) Appl. No.: 18/684,328

(22) PCT Filed: Aug. 18, 2022
(86) PCT No.: PCT/JP2022/031190

§ 371 Date: Feb. 16, 2024

(30) Foreign Application Priority Data
Aug. 19, 2021 (JP) 2021-133948

(51) Int. Cl. F16C 3/02; G01R 29/08

(52) U.S. Cl. CPC F16C 3/026; G01R 29/0821; F16C 2208/02; F16C 2240/26; F16C 2240/40; F16C 2380/00

(57) ABSTRACT

Provided is a rotation transmission shaft unit that is easy to install and that can effectively transmit rotation at high rotational speed and high torque. Also provided are a transmission device and a test device that use the shaft unit and transmit high torque and high rotation over a long span.

A rotation transmission shaft unit that is easy to install and axially align and that can rotate at high torque and high speed is realized by providing bearings to both ends of a rigid cylinder and rotatably support, by using the bearings, a central shaft made of a fiber-reinforced resin. Stability of the axial position of the central shaft can be achieved simply by supporting the rigid cylinder of the shaft unit, and since the rotation transmission shaft unit is a unit, it is easy to attach in and detached from an installation position and is easily centered with respect to the axis of a rotating machine, and because rotation can be transmitted over a long span, the speed of a motor test bench and an EMC test device can be increased.

### TECHNICAL FIELD

The present invention relates to a rotation transmission shaft unit that can effectively transmit rotation at high rotational speed and high torque, and is easy to install.

The present invention also relates to a transmission device for a motor test bench using above shaft unit, and a transmission device and a testing device, using the shaft configuration, which transmits high torque and high rotation between mechanical rotation devices such as motor and generator that exist inside and outside of an electromagnetic anechoic chamber, but intercepts electromagnetic noise.

In the device used for the motor test bench for motor testing, a rotation transmission device with high installation accuracy, which can transmit high speed rotation and high torque between a motor and load, can be obtained. And also, in the device for conducting EMC evaluation testing of an electric motor and an inverter system for moving power of vehicle used in EV (Electric Vehicle), HV (Hybrid Vehicle), PHEV/PHV (Plug-in Hybrid Vehicle) and FCV (Fuel Cell Vehicle), etc. as a component in an electromagnetic anechoic chamber while simulating the driving state of an actual vehicle, a rotation transmission mechanism suitable for use with unprecedented long span and high speed rotation can be obtained.

### BACKGROUND ART

A rotation transmission means of a form that thrust force and torque reaction force are borne by a rigid tube, and only rotational force is transmitted by a rotating shaft by accommodating the rotating shaft in the rigid tube was known as a torque tube in the field of power transmission of vehicles.

Such outside rigid cylinder in the torque tube of the vehicle has been used for rotational force transmission, etc. at a portion with suspension movements of the vehicle, because it has an advantage that it is not required for a rotational force transmission mechanism of the shaft to deal with swinging movements, and it simply protects the rotating shaft effectively, since the thrust force is borne by the rigid tube even when a suspension is in swinging movement state.

However, while conventional torque tube has a metal shaft inserted into a metal rigid tube, the bearings that rotatably support the shaft are located near the center of the rigid tube in the longitudinal direction, for example, as in Patent Document 1, or the shaft of a rotation device to which the rotating shaft is connected supports the rotating shaft instead of the metal rigid tube, for example, as in Patent Document 2, it is not versatile as a single shaft unit, nor is it assumed to transmit high speed rotation such as, for example, 20,000 revolutions per minute.

In the conventional support of the rotating shaft as described in said Patent Document 2, centering of the rotary shaft is not guaranteed by the torque tube alone, and is dependent on the axle of the drive device and driven device, because the rotary shaft is supported by the drive and/or driven rotation axle to be connected, shaft alignment of the rotation transmission shaft, in devices such as motor test benches where long span rotation transmission is required, was very difficult.

In addition, since the rotating shaft was made of metal, it was impossible to achieve high speed rotation such as 20,000 revolutions per minute because the skipping rope phenomenon occurs when the distance between the bearings supporting the rotating shaft gets longer.

In the field where high speed rotation transmission device is used, conventionally, EMC testing of a driving power motor for a vehicle has been conducted with a sample apparatus (motor) being set to operating state (such as standing-by/running). However, in the running state, the motor was not in the state of actual on the road of the vehicle, but in idling state.

Also, EMC testing of an inverter for motor control was not done in loading state simulating vehicle running on the road state as previously mentioned, even though the motor was connected as a load.

For such conventional EMC evaluation methods, the international standards, CISPR 25 Edition 4:2016 (emission measurements) and ISO 11452-2:2019 (immunity testing), were developed and regulations for conditions regarding test setup were made. According to these conditions, the electric motor which is the sample set in the electromagnetic anechoic chamber must be mechanically connected to the load motor outside of the electromagnetic anechoic chamber.

However, when the shaft, which mechanically connects the electric motor and the load motor and rotates at high speed, penetrates inside and outside of the electromagnetic anechoic chamber through a hole in a wall of the electromagnetic anechoic chamber, it is defined by above mentioned international standards that the distance between the sample apparatus (the electric motor) and tip of a radio wave absorber attached to the inside wall of the electromagnetic anechoic chamber should be 1000 mm or more. Therefore, the distance between the electric motor and the load motor will have to be 1500 mm or more considering mechanical mechanism parts such as wave absorber and connecting couplers.

When a shaft of 1000 mm or longer as shown in test setup drawings of the international standards is used and is rotated at high speed, the weight and deflection of the shaft cause skipping rope phenomenon and there is a risk that the equipment is damaged, but no special countermeasure is defined in the international standards.

Conventionally, in order to avoid the skipping rope phenomenon, the length of the shaft portion which rotates at high speed was tried to be made as short as possible by installing a speed reducer at a position close to the electric motor tested in high speed rotation state, and reducing the rotation speed of the shaft connected to the load motor by a fraction to a few tenths of the revolution.

However, the installation of the speed reducer between the electric motor and the load motor requires its cooling system and temperature management, maintenance of mechanical parts, and countermeasure against static electricity or electromagnetic wave. Furthermore, because the installation of the speed reducer between the shafts causes inclusion of uncertain factors such as efficiency of the speed reducer in evaluation testing of the electric motor, the evaluation must be performed considering these factors adding to the uncertainty of the electric motor itself.

As a conventional example of light weight technology for rotational force transmission device, there was one in the form of Patent Document 3.

This document describes the use of CFRP in rotational force transmission means for weight reduction and rigidity increase in a vehicle propeller shaft, reciting as “the rear propeller shaft 44 is a hollow pipe made of carbon fiber-reinforced plastic (CFRP) aiming weight reduction and rigidity increase because there is plenty of space available, as described below” (refer to paragraph 0044). However, this invention is a vehicle propeller shaft and it has nothing to do with EMC testing of the electric motor, nor does it demonstrate rotational force transmission between inside and outside of the electromagnetic anechoic chamber in EMC testing in terms of required torque and rotation speed.

Patent Document 4 also, discloses “a shaft for power transmission being a pipe shaped CFRP (carbon fiber-reinforced plastic) member formed by CFRP, light weight high strength material” (refer to paragraph 0018) as a highly rigid and light weight rotation transmission shaft, but it is just a shaft which is not for the test bench or the EMC testing nor does it have a structure that the rotational shaft is installed within a rigid cylinder.

Also, the use in Patent Document 3 and 4 is not intended to use from a low speed rotation to a high speed rotation of 15000 rpm or higher which was achieved by the present invention.

In the prior art related to dynamo testing and EMC testing of the motor used for an electric automobile, etc., no patent document, which discloses invention that complies with a requirement for high speed rotation over a long span such as above mentioned international standards, is found.

### CITATION LIST

### Patent Documents

[Patent Document 1] JP-A-2009-280053
[Patent Document 2] JP-A-2006-143130
[Patent Document 3] JP-A-2016-055658
[Patent Document 4] JP-A-2011-017413

### SUMMARY OF THE INVENTION

### Problem to be Solved by the Invention

When using a versatile rotation transmission shaft that can be used in a motor test bench, etc., it involves great difficulty in the axis alignment work to align the shaft accurately on dynamo side and motor side of the rotational shaft. In a device in which rotation transmission is performed between drive side and driven side, subjects considered as problems to be solved by the invention of the present application are: a problem of achieving making centering work easy; also a problem of achieving high speed rotation even with a long span between the rotational force input and output sides of the rotating shaft; furthermore in addition to these, a problem of achieving superior radio wave cut off as well as high speed rotation and high torque transmission in a device in which radio wave cut off between drive side and driven side is required.

When a drive source rotation device and a driven rotation device are connected by the rotational shaft, both of the drive source device and the driven rotation device has to be fixed on a floor and the axis alignment of the rotational shafts between the drive source device and the driven device has to be highly accurate. Therefore, all of the drive source device, the driven rotation device and the rotational shaft connecting both have to be accurately aligned. For this alignment work, the bearings supporting the rotational shaft near both ends have to be fixed on a surface table on which the drive source and the driven rotor are fixed, the rotational shaft being accurately supported by the bearings.

In addition, in a rotation transmission mechanism using a conventional shaft, it was impossible to achieve high speed rotation such as 20,000 revolutions per minute in a long span mechanism in which the distance between supporting bearings is, for example, 700 mm, because the skipping rope phenomenon occurs.

Furthermore, since a hole has to be made in the wall of the electromagnetic anechoic chamber and the rotational shaft rotating at high speed has to penetrate through the hole in the testing of the rotation devices in the electromagnetic anechoic chamber, the blocking of electromagnetic wave of the electromagnetic anechoic chamber inevitably be inferior compared to a state with no hole.

Also, because there is inversely proportional relationship between the torque of the motor and the reduction ratio of the speed reducer, installing the speed reducer decreases the rotating speed at the output shaft of the speed reducer but increases the torque. Thus, the rotation number of the connected load motor can be reduced to a fraction, but several times of torque is required. In other words, installing the speed reducer allows the electric motor to operate at high rotation speed, but reduced torque results in insufficient testing of the electric motor.

Therefore, it is desirable to use a mechanism in which the ratio of rotation speed and the ratio of torque are 1:1 without installing a speed reducer, but in the prior art, the testing equipment without a speed reducer makes the length of the connecting shaft between the electric motor being tested and the load motor longer and causes skipping rope phenomenon when rotating at high speed, and may damage the apparatus/equipment.

Therefore, there is a problem to be solved that a rotation transmission mechanism with abilities that transmittable torque is high, the length of the shaft is long while no issue is raised even at high speed rotation, and electromagnetic noise which can pass through the wall of the electromagnetic anechoic chamber is completely intercepted or is reduced as less as possible is to be provided.

The present invention provides a rotation transmission shaft unit, a rotation transmission mechanism and an electromagnetic anechoic chamber that can solve these problems. The present invention has solved these problems and thus can provide easily and with high accuracy a testing apparatus of rotational electric apparatus such as motors, etc. under various conditions such as low speed rotation-high torque, and high speed rotation-low torque, and can provide a device which achieves EMC testing thereof.

### Means for Solving the Problems

The invention of the present application comprises following embodiments.

[1] A shaft unit that transmits rotation, comprising:
a central shaft; and
a rigid cylinder through which the central shaft penetrates, wherein the rigid cylinder has bearings at both ends that rotatably support the central shaft at both ends of the rigid cylinder,

wherein the central shaft is made of fiber-reinforced plastic.

[2] The shaft unit according to [1], wherein the distance between the bearings at both ends is 700 mm or more.

[3] The shaft unit according to [2], the central shaft has flexural rigidity vs mass ratio with which rotatable at 20,000 revolutions per minute or more.

[4] The shaft unit according to any one of [1] to [3], wherein the central shaft is made of carbon fiber-reinforced plastic.

[5] The shaft unit according to any one of [1] to [4], wherein a central shaft unit and the rigid cylinder are conductive, and the central shaft unit and the rigid cylinder are electrically conducted at bearing locations on both ends.

[6] The device according to [5], wherein the means for electrically conducting the central shaft and the rigid cylinder comprises a conductor that occupies a space between the central shaft and the conductive rigid cylinder.

[7] A rotation transmission device between rotating machines comprising the shaft unit according to any one of [1] to [6], drive side base, and driven side base, wherein said shaft unit is fixed to drive side base and driven side base at both end positions of the rigid cylinder, respectively.

[8] An electromagnetic anechoic chamber having the rotation transmission device according to [7].

The inventors of the invention of the present application have found that, in a test bench that requires the shaft to transmit rotation, the simple rotational shaft supported by bearings fixed on the floor requires adjustment of mutual position of the two bearings, which causes difficulty on centering work, but in contrast to this, with a configuration in which the rotational shaft is supported at both ends of the rigid cylinder, a shaft of so called torque tube type, both ends of the rotational shaft can be axially aligned by only fixing the rigid cylinder on the floor, so that only accurate positioning of the rigid cylinder makes axial alignment with both of rotation drive source and driven rotation device easy.

Also, the inventors of the invention of the present application have found that, in order to achieve high speed rotation without skipping rope phenomenon, the ratio of flexural rigidity to mass density of the rotating shaft (referred to herein as the flexural rigidity vs mass ratio), is to be, the rotational shaft should have high flexural rigidity while having light weight. And, for this purpose, they have found that a shaft made of carbon fiber-reinforced plastic can be used.

The inventors have found also that because carbon is contained in the shaft made of carbon fiber-reinforced plastic, electric charge conducted in the rotational shaft can be immediately released to ground potential via the metal bearings.

Furthermore, they have found that the shaft and the conductive rigid cylinder, for example metal rigid cylinder cover covering the shaft, penetrate the wall of the electromagnetic anechoic chamber, and high frequency electromagnetic wave can be shielded by conductive fiber electrically connected to the metal cover surrounding circumference of the shaft surface.

When a metal shaft is used, it is impossible to prevent skipping rope phenomenon with bearing span of over 700 mm.

In the present invention, torque capacity of a load motor is maximally utilized instead of using a speed reducer. The distance between the electric motor, which is an apparatus to be tested, and the load motor outside of the electromagnetic anechoic chamber becomes longer because of not using the speed reducer, however, using a shaft made of carbon fiber-reinforced plastic results in light weight and high rigidity, and from low speed rotation to high speed rotation, no problem arises.

The term “conductive” in the terms “conductive rigid cylinder” as used herein refers to material having conductivity of metals such as aluminum, iron, copper and brass, i.e., volume resistivity value of 2×10−8 Ωm to 100×10−8 Ωm at room temperature, and the term “rigid” refers to a degree of rigidity of the level which these metals have.

Also, the term “test bench” refers to a facility in which a rotation force drive source fixed on a floor is connected with a driven rotation device fixed on the same floor to perform some sort of test such as output testing of the rotation drive source or radio wave testing in rotating state.

Furthermore, the term “shaft length” refers to the distance between the bearings at both ends of the conductive rigid cylinder.

For the conductive rigid cylinder, cylindrical shape is most preferable, but since it is a rigid body, it is enough as far as positional fluctuation of the conductive rigid cylinder does not occur. Therefore, once the rigid cylinder is fixed onto the floor where equipment is installed, supporting position of the rotating shaft is fixed, which results in stable rotation axis position of the rotating shaft required for axis alignment of the rotating shaft. If the conductive rigid cylinder is fixed onto the floor of the installation site at positions near each end, positioning of the bearings relative to the floor of the installation site becomes more rigid than the positioning that depends on the rigidity of the rigid cylinder, and bearing positioning of the rotating shaft becomes most accurate.

This floor may be a surface table so that the relative position of both ends of the rotational shaft is defined and immovable.

Also, since the conductive rigid cylinder which serves as a housing of the rotational shaft is a rigid body, the position fluctuation during operation at the joining portion with the wall as though the shaft penetrates the wall is extremely small.

A grounding effect can be expected by blocking the shaft rotating at high speed with a shield box which is the conductive rigid cylinder, and supporting the rotational shaft using the metal bearings at both ends of the shield box.

Furthermore, a shielding effect is improved by occupying the space with contacting conductive resin brushes on the shaft periphery at both ends of the shield box.

The shield box is conductive and electrically connected with the electromagnetic blocking wall to maintain electromagnetic shielding.

### Advantageous Effects of Invention

In the shaft unit of the present invention, since the rotating shaft is rotatably supported by the bearings of the rigid cylinder at both ends of the cylinder, axial alignment of the rotation axis of the rotating shaft is secured by the rigid cylinder and it is not necessary to align using the rotation axis of the rotation apparatus to which the rotating shaft is connected. In addition, since the rotating shaft supported by the rigid cylinder and the bearings at both ends thereof is made of fiber-reinforced plastic, the skipping rope phenomenon is prevented even if the rigid cylinder has unprecedentedly long length, and a high speed rotation such as 20,000 revolutions per minute or more can be achieved. Therefore, there is a effect that it is possible to transmit high speed rotation even when the distance between two rotation apparatus transmitting rotation by shaft is long.

In addition, in the shaft unit of the present invention, the rigid cylinder of the unit guarantees the axis positioning accuracy of the rotating shaft, and therefore, even with lower positioning accuracy requirements for the drive source with which the shaft unit transmits rotations is applied, positioning which enables high-speed rotation is easily executable because the positioning accuracy in the shaft unit is guaranteed by the rigid cylinder.

In other words, the axial alignment of the rotating shaft is simple because the spatial positioning of the rotation support bearing of the rotating shaft at the installation position is executed once the positioning of the rigid cylinder of the unit is executed, and

since the conductive rigid cylinder is a rigid body, bearing positioning of the rotating shaft is accurate, which result in an effect of preventing skipping rope effect.

Also, since the conductive rigid cylinder which serves as a housing of the rotational shaft is a rigid body, the position fluctuation during operation at the joining portion with the wall as though the shaft penetrates the wall is extremely small.

The rotating shaft is made of fiber-reinforced plastic, and its flexural rigidity is sufficiently high relative to its mass, therefore, it is effective that even if the distance between the bearings at both ends of the rigid cylinder is 700 mm or more, the skipping rope phenomenon does not occur at high-speed rotation. Carbon fiber-reinforced plastic or aramid fiber-reinforced plastic is the most suitable as the fiber-reinforced plastic. And if carbon fiber is used, it is also the most suitable for EMC testing equipment using an electromagnetic anechoic chamber as described below.

In the case of the electromagnetic anechoic chamber using the shaft unit according to the invention of the present application, the EMC testing defined by international standards become possible because even if a wide range of torque from low to high torque is applied, and even if rotation from slow speed of several tens of revolutions per minute to high speed rotation of several tens of thousands revolutions per minute which are required by EMC testing are actually realized.

Preventing skipping rope phenomenon is achieved by using carbon fiber-reinforced plastic for the shaft.

Therefore, transmitting higher torque and higher rotation than conventional ones are achieved, for example, using 900 mm shaft length or even with longer one, at 20,000 revolutions per minute and 350 Nm of transmission torque can be realized.

### BRIEF DESCRIPTION OF DRAWINGS

FIG. 1 is a drawing showing an example of a shaft unit of the present invention.

FIG. 2 is a drawing showing an example of a rotation transmission device between rotating machines using the shaft unit of the present invention.

FIG. 3 is a drawing of an electromagnetic anechoic chamber having the rotation transmission device using the shaft unit of the present invention.

### EMBODIMENTS FOR CARRYING OUT THE INVENTION

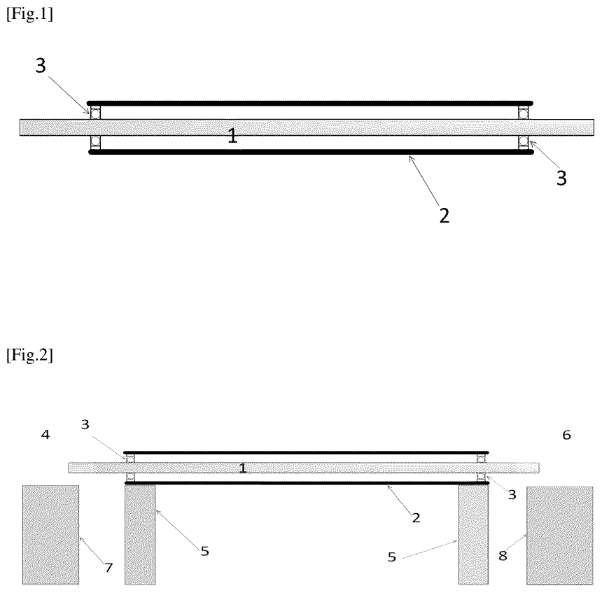

FIG. 1 is an example of a shaft unit of the present invention. Central shaft 1, which transmits rotation, is made of fiber-reinforced plastic, and said central shaft 1 penetrates rigid cylinder 2 in the direction of axis of the rigid cylinder 2 having rigidity, and is rotatably supported by bearings 3 at both ends of the rigid cylinder 2.

The rigid cylinder 2 can have a distance of 700 mm or more between the bearings, and the distance between the bearings may be 1400 mm. A hollow shaft made of carbon fiber-reinforced plastic is preferable for the shaft 1 to realize a rotational shaft which is light weight and can withstand high speed rotation.

The rigid cylinder 2 is preferably made of cylindrical metal and has a thickness which is enough not to resonate or deform even at high rotational speed such as, for example 20,000 revolutions per minute.

In addition, the shaft unit of the present invention, in which the central shaft 1 and the rigid cylinder 2 are assembled through the medium of bearings 3, can be used for various applications as a shaft unit, because as long as the rigid cylinder 2 of the shaft unit is firmly installed, positioning of the bearings 3, which are the supporting points of the rotating shaft, is executed, drive side and driven side of rotation transmission do not have to guarantee the positioning accuracy of the rotation axis of the central shaft.

FIG. 2 shows an example of a motor test bench with the shaft unit of the present invention.

As a drive side rotating machine, for example, motor 4 applies rotation force to the central shaft 1 via some kind of rotation transmission joint, and the rotation force is transmitted by the central shaft 1 to dynamo 6 as a driven side rotating machine, also via central shaft 1 and some kind of rotation transmission joint.

The motor 4 and the dynamo 6 are fixed onto solid installation bases 7 and 8, while the rotatable support of the central shaft 1 is provided by the bearings 3 installed at both ends of the rigid cylinder 2, wherein the rigid cylinder 2 is installed and fixed to the installation base 5.

Since rotation axis centering accuracy of the central shaft is made by the bearings 3 and the rigid cylinder 2, more degrees of freedom of rotation transmission joints are obtained on motor 4 side and dynamo 6 side.

In addition, the central shaft and the rigid cylinder 2 can be insulated from vibration caused by the motor 4 and the dynamo 6, because they are separated from the support bases of the motor 4 and the dynamo 6.

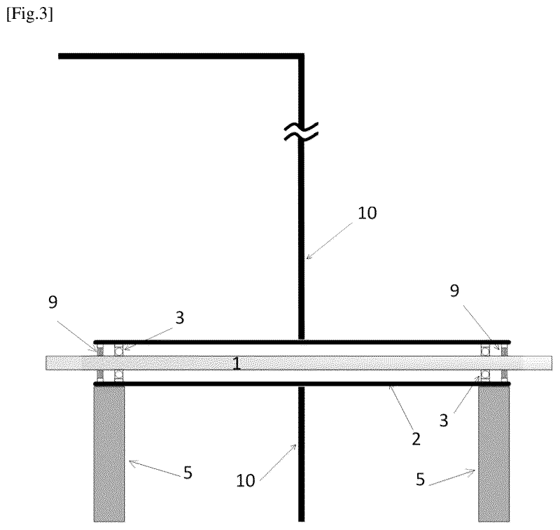

FIG. 3 shows a partial cross-sectional view of a shield room wall portion at the shaft penetration position of an electromagnetic shield room equipped with the shaft unit of the present invention, which can be used for EMC testing, etc.

For the purpose of electromagnetic shielding, electromagnetic shield brushes 9 are provided just outside of the bearings of the rigid cylinder 2. Also in FIG. 3, as in FIG. 2, assuming that the drive rotating machine is located on the left side of the figure and the load rotating machine is located on the right side, and the inside of the shield room is on the left side of FIG. 3, the right side of shield wall 10 is outside of the shield room.

Electromagnetic shield is provided by direct contact, contact via a conductive flexible material, for example, metal mesh, or connecting flexible metal bellows to the shield wall and the conductive rigid cylinder 2, etc., so the shield wall 10 is electrically conductive to the rigid cylinder 2.

The conductive rigid cylinder 2 is connected to the shield wall 3 and may also be fixed to floor where the device is installed, for example, near the both ends and via the installation base 5, but it is not necessarily to be fixed at both of end positions.

The central shaft 1 is made of carbon fiber-reinforced plastic, and the central shaft and the conductive rigid cylinder 2 are electrically connected to each other by bearings 3 and conductive brushes 9.

The conductive brushes occupy the space between the conductive rigid cylinder 2 and the entire circumference of the central shaft, at a density sufficient to shield electromagnetic waves of the desired frequency.

Leakage of electric current or electromagnetic wave from one side to the other side of the wall is prevented since the electric current does not penetrate through the conductive shaft but escape from the housing 2 to the wall via the conduction means between the rotational shaft and the housing 2. The shield wall and the conductive housing do not have to be completely sealed as far as electromagnetic wave leakage is sufficiently small.

This electromagnetic anechoic chamber is an electromagnetic anechoic chamber suitable, for example, for use of EMC testing of an electric motor for an electric vehicle.

The conductive brushes 9 may be metal brushes.

The electromagnetic anechoic chamber according to the present invention using rotation transmission mechanism achieves performing testing transmitting rotational motion at high speed rotation with unprecedented high torque while maintaining electromagnetic shielding as previously mentioned. Therefore, the electromagnetic anechoic chamber for EMC testing using this mechanism enables testing at unprecedentedly high speed rotation.

The electromagnetic anechoic chamber according to the present invention can effectively cut off the electromagnetic wave of 9 kHz to several GHz, which is required by EMC testing.

### LIST OF REFERENCE NUMERALS

1. central shaft
2. rigid cylinder
3. bearing
4. drive rotating machine
5. shaft unit support base
6. load rotating machine
7. drive side base
8. load side base
9. electromagnetic shield brush
10. shield wall

1. A shaft unit that transmits rotation, comprising:
a central shaft; and
a rigid cylinder through which the central shaft penetrates, wherein the rigid cylinder has bearings at both ends that rotatably support the central shaft at both ends of the rigid cylinder,
wherein the central shaft is made of fiber-reinforced plastic.

2. The shaft unit according to claim 1, wherein the distance between the bearings at both ends is 700 mm or more.

3. The shaft unit according to claim 2, wherein the central shaft has flexural rigidity vs mass ratio with which rotatable at 20,000 revolutions per minute or more.

4. The shaft unit according to claim 1, wherein the central shaft is made of carbon fiber-reinforced plastic or aramid fiber-reinforced plastic.

5. The shaft unit according to claim 3, wherein a central shaft unit and the rigid cylinder are conductive, and the central shaft unit and the rigid cylinder are electrically conducted at bearing locations on both ends.

6. The shaft unit according to claim 5, wherein the means for electrically conducting the central shaft and the rigid cylinder comprises a conductor that occupies a space between the central shaft and the conductive rigid cylinder.

7. A rotation transmission device between rotating machines having the shaft unit according to claim 1, wherein the shaft unit is fixed to drive side base and driven side base at both end positions of the rigid cylinder, respectively.

8. An electromagnetic anechoic chamber having the shaft unit according to claim 5.
